(19) United States
(12) Patent Application Publication
(10) Pub. No.: US 2022/0271542 A1
(43) Pub. Date: Aug. 25, 2022

(54) EXPANSION MODULE FOR A DC CHARGING POINT AND CORRESPONDINGLY EXTENDED DC CHARGING POINT

(71) Applicant: Dr. Ing. h.c. F. Porsche Aktiengesellschaft, Stuttgart (DE)

(72) Inventors: Raoul Heyne, Wiernsheim (DE); Timo Massierer, Ludwigsburg (DE)

(21) Appl. No.: 17/676,501

(22) Filed: Feb. 21, 2022

(30) Foreign Application Priority Data
Feb. 22, 2021 (DE) 10 2021 104 129.5

(51) Int. Cl. H02J 7/00; B60L 53/14; B60L 53/30; H01H 39/00

(52) U.S. Cl. CPC H02J 7/0031; B60L 53/14; B60L 53/305; H02J 7/00304; H01H 39/006; H01H 2039/008

(57) ABSTRACT

An expansion module (1) for a charging point has a DC measuring device (3) configured, when installed in the charging point, to carry out a current and voltage measurement on the DC charging lines of the charging point. An evaluation unit (2) is coupled to the DC measuring device (3) and calculates an amount of energy drawn based on the current and voltage measurement carried out by the DC measuring device (3). A display unit (4) is coupled to the evaluation unit (2) or is integrated therein. The evaluation unit (2) further has a switch-off interface (5) to provide a switch-off signal at the switch-off interface (5) if, on the basis of the current and/or voltage measurement carried out by the DC measuring device (3), it is determined that an overcurrent or short circuit is present. A charging point equipped with the expansion module (1) also is provided.

### CROSS REFERENCE TO RELATED APPLICATION

This application claims priority under 35 USC 119 to German Patent Appl. No. 10 2021 104 129.5 filed on Feb. 22, 2021, the entire disclosure of which is incorporated herein by reference.

### BACKGROUND

Field of the Invention The invention relates to an expansion module for a DC charging point (direct-current charging point) and to a DC charging point correspondingly equipped with the expansion module.

Related Art There are two basic possibilities for charging electric vehicles, namely, charging the vehicles with direct current (DC) or with alternating current (AC). Accordingly, the various charging stations used worldwide can provide both types of charging current. However, charging by means of direct current has a clear time advantage over charging with alternating current. For this reason, fast charging points are DC charging points. As an example, the 800 volt HPC charging points (HPC: High Power Charging) shall be mentioned here, at which charging powers of more than 270 kW can be attained. With this charging power, modern electric vehicles, such as the Porsche Taycan, can be recharged with energy for a range of up to 100 km in just five minutes.

The global electricity grid is operated almost exclusively with alternating current. Therefore, alternating current is converted into direct current at fast charging points by using converters that either are installed directly in the charging point itself or are arranged in an outsourced power unit coupled to one or more charging points. Modern charging points can complete this current conversion with efficiencies in the range of 90% or more.

Since Apr. 1, 2019 the amount of current drawn at a DC charging point has had to be billed according to the strict requirements of the calibration law. For this purpose, the direct current has to be measured in compliance with the calibration law during the charging process. Accordingly, the measurement results must be displayed to the consumer in a suitable form and in a tamper-proof manner and at the same time must be checkable. The electricity meters used in households are examples of current meters that are compliant with the calibration law. These household electricity meters measure the current used and at the same time display the consumption.

Present-day charging points usually measure the current at the grid connection on the alternating-current side because the measurements at these locations can be ascertained in a manner certified in a simple way. If this amount of energy that can be determined therefrom were billed to the customer charging his/her electric vehicle, that would mean that the losses of the charging point, for example the heat losses during the current conversion from AC to DC, would be included in the billing to the customer. Therefore, for the billing at the charging point a certain proportion is deducted at a flat rate from the amount of energy to take account of the losses, or the current is sold by way of flat rates and/or a parking space rental fee in front of the charging point. However, this procedure is incompatible with the requirements of the applicable calibration law, according to which for every driver of an electric vehicle the charging process at the charging point must be comprehensible in a transparent way with regard to the amount of energy drawn and the costs incurred therefor. The amount of energy drawn therefore has to be billed in kilowatt-hours (kWh). To comply with the requirements of the calibration law, there are now DC meters (direct-current measuring devices) that bill for the charging energy in a calibration-officially certified manner. However, at present these DC meters are concentrating exclusively on billing for the current and have no further functionality.

The new standard DIN EN 61851-23, which is currently still in draft form and will come into force in 2021 at the earliest, makes stronger stipulations with regard to further functions that a charging station must comply with. In this respect, according to the new standard, an identification of a short circuit must take place with a very fast switch-off. In this case, the peak current flowing in the event of a short circuit must not exceed the value of 10 kA. A melting integral of 1 MA²s also must not be exceeded. The new stipulations further provide for a fast emergency switch-off to be triggered in the event of a short circuit, in the case of which switch-off the current must fall to a value of less than 5 A within 30 milliseconds. An identification of an overcurrent is demanded as well and must be brought under control with the same conditions applicable to the case of a short circuit. The integration of these functionalities in charging points is associated with the need for new components that have to be installed in the charging station, and these components may lead to problems in terms of space under certain circumstances. These newly demanded stipulations can become problematic for existing and already approved charging systems since their implementation is realizable with a great outlay and therefore possibly no longer in an economically viable way. Furthermore, these already approved charging systems have to be recertified in that the newly demanded functions have to be checked, thereby requiring further expenses.

Against this background, the problem addressed by this invention can be considered that of implementing the further functional demands in accordance with the new DIN charging standards on an existing, already certified charging point in such a way that this does not necessitate major conversion measures. A recertification of the existing charging system also is intended to be avoided, if possible, can entail great cost savings.

### SUMMARY

The invention relates to an expansion module for a charging point. The expansion module comprises a DC measuring device configured, in a state installed in the charging point, to carry out a current and voltage measurement on the DC charging lines of the charging point. The DC measuring device can be a calibration-officially certified direct-current measuring device configured for determining the current intensity and the electrical voltage. The DC measuring device generally can be configured for measuring at least two variables.

The expansion module also may comprise an evaluation unit that is coupled to the DC measuring device and that is configured to calculate a resultant amount of energy drawn on the basis of the current and voltage measurement carried out by the DC measuring device. On the basis of the determined amount of energy drawn, it is possible to carry out the billing for the charging process at the charging point.

The expansion module further may comprise a display unit that is coupled to the evaluation unit or is integrated therein. The display unit can be configured to display information, for example the energy presently flowing through the charging cables of the charging point on the basis of the current and voltage measurement, and also the payment due after the charging process for the charging energy drawn.

The evaluation unit further may have a switch-off interface that is configured to provide a switch-off signal if, on the basis of the current and/or voltage measurement carried out by the DC measuring device, it is determined that an overcurrent is present. The switch-off signal can be generated by the evaluation unit, and the switch-off interface can be on the evaluation unit. The switch-off signal can communicate the existence of an overload to other components of the charging point. As a result, the charging point is switched to be free of voltage. The detectable overcurrent may be due to a short circuit or an overload, i.e. an excessively high current flow possibly above the designated maximum current. The DC measuring device is configured to measure current and voltage extremely accurately, and these values can readily be utilized for an identification of the overcurrent. Both a short circuit and an overload can be identified by a rise or fall in the voltage by a specific value in a specific time and/or an excessively high current.

The expansion module can be an expansion of a calibration-compliant DC meter procured commercially from a manufacturer as a bought-in part and can be supplemented by further functions via the further components within the expansion module so that the expansion module satisfies all applicable legal/official requirements. Precisely in the case of distributed systems in which the charging points and the power electronics providing the charging current are separated from one another, as is usually the case in larger charging parks, it is possible to install a customary DC meter certified as calibration-compliant with an additional function (which corresponds to the expansion module according to the invention) in the charging point, where enough structural space is still available and the DC meter already has been included in the planning.

In accordance with further embodiments, the DC measuring device can have at least three measurement taps and two of the measurement taps can correspond to two ends of a first metal conductor arranged on the DC measuring device. An opening can be provided at each end of the metal strip so that each of the ends can be connected to the DC busbar within the charging point.

In accordance with further embodiments, one measurement tap can be at an end of a second metal strip arranged on the DC measuring device. This third measurement tap can be secured to the other DC busbar by a screw connection and enables a potential difference with respect to one of the other two measurement taps at the first metal strip (i.e. ultimately the charging voltage) to be ascertained.

The invention further relates to a charging point for charging electric vehicles, and the charging point comprises the expansion module described herein. The charging point can be, except for the additional expansion module according to the invention, a customary charging point at which electric vehicles can be charged by direct current. The expansion module can be installed in the charging point so that its measurement taps are coupled functionally to the DC current-carrying voltage lines, for example the DC busbars.

In accordance with further embodiments, the switch-off interface can be coupled to a control device of the power component of the charging point or to a charging station comprising the charging point. The power component can be understood to mean the electronic component or component group that converts the alternating current to direct current and provides the charging current at suitable voltage and current intensity. In this case, the switch-off interface can be coupled to a control device of the power component, such that as necessary the switch-off signal has the effect that the control device of the power component pulls the pilot line of the charging system to a suitable potential. As a result, the normative emergency switch-off is initiated and the new normative stipulations are complied with temporally. In this case, the DC output contactors can be opened, as a result of which the charging point can be switched to be free of voltage very rapidly. The pilot line of the charging system can be a monitoring line of the entire HV charging system, via which locally occurring disturbance functions can be reported to the overall system to switch the charging system to be free of voltage.

In accordance with further embodiments of the charging point, the switch-off interface can be coupled to a switch interconnected in a monitoring signal path of the charging point. In this case, the switch can be part of the control pilot (CP) of the charging point, i.e. be functionally coupled thereto. The control pilot is understood to mean a line between electric vehicle and charging point by means of which safety checks can be carried out and via which communication with the electric vehicle is carried out. Furthermore, the electric vehicle can signal via the control pilot that it is ready for the charging process. More particularly, the expansion module can be installed in the charging point so that as necessary the expansion module directly interrupts the control pilot in the communication between vehicle and charging point (principally the charging control in this charging point). The switch then functions as an interrupter of the control pilot and can be actuated directly by the expansion module. Secondly, the switch can correspond to an interrupter of the pilot line of the superordinate charging system. Apart from detection of a short circuit or an overcurrent, the switch-off signal can be communicated to the switch, and thus interrupt the pilot line independently, i.e. without a detour via the control device of the power electronics. This enables the charging point to undergo a fast emergency switch-off that fulfils the normative stipulations.

In accordance with further embodiments, at least one switch can be arranged in DC current-carrying charging lines of the charging point and/or in charging lines of a charging station comprising the charging point. The control terminal of the at least one switch is coupled to the switch-off interface of the expansion module. In this regard, the expansion module can be configured to ascertain the switching state of the at least one switch. The at least one switch mentioned here is different than the switch within the monitoring signal path of the charging point, as mentioned in the previous paragraph.

In accordance with further embodiments of the charging point, the at least one switch can be a switching contactor. In this embodiment, the expansion module can independently interrupt the current flow in the DC path by means of the at least one switching contactor if an overcurrent or a short circuit is identified. That has the advantage that no change to the internal structure of the charging point and no adaptation of the charging point to the charging station need be effected.

The switches can comprise pyroswitches and can additionally or exclusively comprise fuses with a tripping or switch-off characteristic suitable for satisfying normative requirements in the event of a short circuit. Pyroswitches (pyrotechnic DC voltage switches) have the advantage that they are electrically drivable and can thus also be tripped if the current is too high only for a short time, before it would cause a fusible link to trip. Accordingly, the pyroswitches can also be used as switches, but only once and would then have to be replaced. This fact can be regarded as advantageous since, after a short circuit or overcurrent, according to the standard, the operation of the charging point should be ceased until a service engineer rectifies the problem.

In summary, therefore, each of the switches arranged in the DC current-carrying charging lines can comprise a switching contactor, a pyroswitch or a combination of both in a series circuit. Likewise, each of the switches can comprise a combination of a switching contactor and a fusible link in a series circuit. If a switch does not function, by virtue of its sticking, for example, it would still be possible to interrupt the current flow in the case of a fault by means of the tripping of the fuse.

Features mentioned above and those that will also be explained below can be used in the combination indicated and also in other combinations, or by themselves, without departing from the scope of the invention.

Further advantages and configurations of the invention are evident from the following description and the accompanying drawings.

### BRIEF DESCRIPTION OF THE DRAWINGS

FIG. 1 shows an exemplary embodiment of the expansion module according to the invention.

FIG. 2 shows a possible interconnection of the expansion module illustrated in FIG. 1 in a charging point.

### DETAILED DESCRIPTION

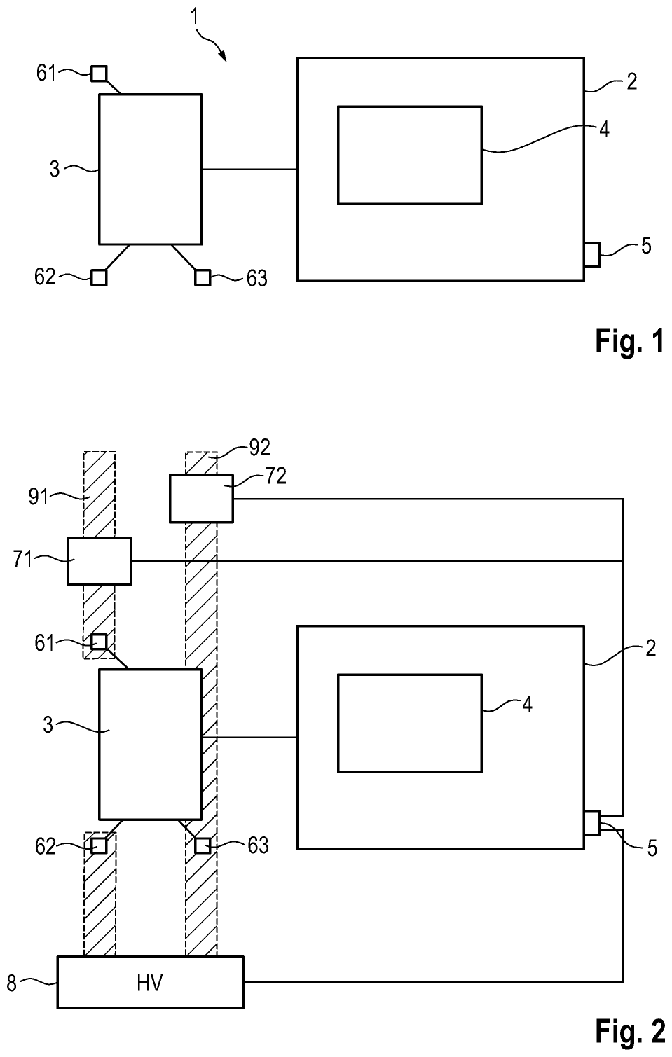

FIGS. 1 and 2 schematically illustrate an embodiment of the invention. The elements shown in the figures may be implemented in various forms of hardware, software or combinations thereof. Preferably, these elements are implemented in a combination of hardware and software on one or more appropriately programmed general-purpose devices that may include a processor, memory and input/output interfaces. The term “connected” as used herein is defined to mean directly connected to or indirectly connected with through one or more intermediate components. Such intermediate components may include both hardware and software-based components.

It will be appreciated by those skilled in the art that the block diagrams presented herein represent conceptual views of illustrative circuitry embodying the principles of the disclosure. Similarly, any functions or methods implied by these block diagrams may be represented in computer readable media and so executed by a computer or processor, whether or not such computer or processor is explicitly shown.

FIG. 1 schematically depicts the construction of an exemplary expansion module 1. As already described, the expansion module 1 comprises a DC measuring device 3, which, in this example comprises three measurement taps 61, 62, 63 for measuring at least two measurement variables. The DC measuring device 3 is configured, in a state installed in the charging point, to carry out a current and voltage measurement on the DC charging lines of the charging point by means of the three measurement taps 61, 62, 63. Furthermore, the expansion module 1 comprises an evaluation unit 2 that is coupled to the DC measuring device 3 and is configured to calculate, on the basis of the current and voltage measurement carried out by the DC measuring device 3, a resultant amount of energy drawn. The evaluation unit 2 is coupled to a display unit 4 that is integrated in the evaluation unit 2 in the example shown. However, the display unit 4 can also be present as a separate component. The display unit 4 is, in any case, driven by the evaluation unit 2 and is configured for displaying diverse information. The evaluation unit 2 further has a switch-off interface 5 and is configured to provide a switch-off signal at the switch-off interface 5 if, on the basis of the current and/or voltage measurement carried out by the DC measuring device 3, it is determined that a case of overcurrent or short circuit is present.

A possible interconnection of the expansion module 1 illustrated in FIG. 1 within a charging point is illustrated in FIG. 2. The elements of the expansion module have already been described with reference to FIG. 1 and will not be explained again.

The first and second measurement taps 61, 62 are both coupled to a first DC line 91 such that, via the first DC line 91, the DC measuring device 3 can carry out a current measurement. The third measurement tap 63 is coupled to a second DC line 92, such that the DC measuring device 3 can carry out a voltage measurement between the third measurement tap 63 and one of the other two measurement taps 61, 62. In the example shown, the switch-off interface 5 is coupled to HV power electronics 8, which perform the current conversion (from AC to DC) and provide the charging current with suitable voltage and suitable current intensity. The switch-off signal can thus be communicated to the HV power electronics 8, for instance to the control device thereof, which can then interrupt a pilot line. The switch-off interface 5 further is coupled to two switches 71, 72, each of which is interconnected in a DC line 91, 92. The switches 71, 72 can be switching contactors or pyroswitches. Likewise, at least one of the switches 71, 72 can be embodied as a combined switch and comprise a series circuit formed by a switching contactor with a fuse switch, i.e. a pyroswitch or a fusible link. In the case of overload, the evaluation unit 2 can drive the two switches 71, 72 via the switch-off interface 5 and bring about an interruption of the DC charging circuit. In the case where both the HV power electronics 8 and the two switches 71, 72 are driven by the evaluation unit 2 via the switch-off interface 5, the switch-off interface can comprise one or two outputs, such that one or two different switch-off signals adapted to the respective receivers are output.

A switch-off of the power electronics can take place by way of a shutdown or stopping of the converter conversion and/or trip the DC contactors of the power electronics.

What is claimed is:

1. An expansion module (1) for a charging point, comprising:
a DC measuring device (3) configured, in a state installed in the charging point, to carry out a current and voltage measurement on the DC charging lines of the charging point;
an evaluation unit (2) coupled to the DC measuring device (3) and configured to calculate a resultant amount of energy drawn based on the current and voltage measurement carried out by the DC measuring device (3);
a display unit (4) coupled to or integrated in the evaluation unit (2);
wherein the evaluation unit (2) further has a switch-off interface (5) and is configured to provide a switch-off signal at the switch-off interface (5) if, on the basis of the current and/or voltage measurement carried out by the DC measuring device (3), it is determined that an overcurrent or short circuit is present.

2. The expansion module (1) of claim 1, wherein the DC measuring device (3) has at least three measurement taps (61, 62, 63) and two of the measurement taps (61, 62) correspond to two ends of a first metal conductor arranged on the DC measuring device (3).

3. The expansion module (1) of claim 2, wherein one measurement tap (63) is arranged at one end of a metal strip arranged on the DC measuring device (3).

4. A charging point for charging electric vehicles, comprising the expansion module (1) of claim 1.

5. The charging point of claim 4, wherein the switch-off interface (5) is coupled to a control device of the power component (8) of the charging point or a charging station that comprises the charging point.

6. The charging point of claim 4, wherein the switch-off interface (5) is coupled to a switch interconnected in a monitoring signal path of the charging point.

7. The charging point of claim 4, wherein at least one switch (71, 72) is arranged in DC current-carrying charging lines (91, 92) of the charging point and/or in charging lines of a charging station comprising the charging point, the control terminal of said at least one switch being coupled to the switch-off interface (5) of the evaluation unit (2).

8. The charging point of claim 7, wherein the switch (71, 72) is a switching contactor.

9. The charging point of claim 7, wherein the switch (71, 72) comprises a pyroswitch.
